(19) United States
(12) Patent Application Publication
(10) Pub. No.: US 2026/0113982 A1
(43) Pub. Date: Apr. 23, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Guan-Lin Chen, Hsinchu County (TW); Kuo-Cheng CHIANG, Hsinchu County (TW); Shi-Ning Ju, Hsinchu City (TW); Chih-Hao Wang, Hsinchu County (TW)

(73) Assignee: Taiwan Semiconductor Manufacturing Company, Ltd., Hsinchu (TW)

(21) Appl. No.: 18/918,100

(22) Filed: Oct. 17, 2024

(51) Int. Cl. H01L 29/423; H01L 29/06; H01L 29/417; H01L 29/66; H01L 29/775; H01L 29/786

(52) U.S. Cl. CPC H10D 30/6735; H10D 30/014; H10D 30/43; H10D 30/6729; H10D 30/6757; H10D 62/121; H10D 64/018

(57) ABSTRACT

A semiconductor device includes a substrate, channel layers disposed over the substrate, a gate structure disposed on the substrate and wrapping around the channel layers, and source/drain structures disposed besides the channel layers and at opposite sides of the gate structure. The channel layers are spaced apart from one another. The gate structure comprises an upper gate feature and interposing gate features between the channel layers. The interposing gate features comprise protrusions protruding into the channel layers.

### BACKGROUND

The semiconductor integrated circuit (IC) industry has experienced exponential growth. Technological advances in IC materials and design have produced generations of ICs where each generation has smaller and more complex circuits than the previous generation, therefore, semiconductor structures need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 illustrate schematic cross-sectional views of a semiconductor device during various stages of a fabrication process according to some embodiments of the present disclosure.

FIG. 14 illustrates FIG. 9 in a three-dimensional view, in accordance with some embodiments.

FIGS. 15-18 illustrate portion of the semiconductor device in FIG. 11 according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

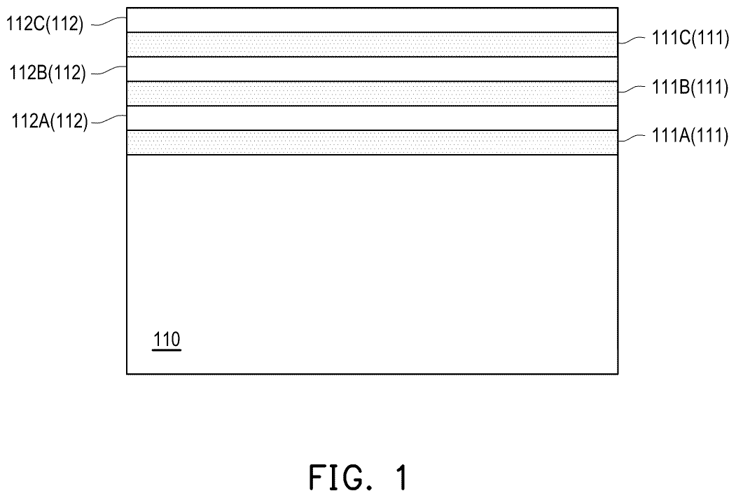

Referring to FIG. 1, a substrate 110 is provided. The substrate 110 may be a semiconductor substrate, such as a bulk semiconductor, a semiconductor-on-insulator (SOI) substrate, or the like, which may be doped (e.g., with a p-type or an n-type dopant) or undoped. The substrate 110 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate, or the like. Other substrates, such as a multi-layered or gradient substrate may also be used.

In some embodiments, the semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In the unillustrated embodiment, the substrate 110 has an n-type region and a p-type region. The n-type region can be for forming n-type devices, such as NMOS transistors, e.g., n-type nano-FETs, and the p-type region can be for forming p-type devices, such as PMOS transistors, e.g., p-type nano-FETs. The n-type region may be physically separated from the p-type region, and any number of device features (e.g., other active devices, doped regions, isolation structures, etc.) may be disposed between the n-type region and the p-type region.

Further in FIG. 1, a multi-layer structure is formed over the substrate 110. The multi-layer structure includes alternating layers of first semiconductor layers 111A, 111B, 111C (collectively referred to as first semiconductor layers 111) and second semiconductor layers 112A, 112B, 112C (collectively referred to as second semiconductor layers 112). For purposes of illustration and as discussed in greater detail below, the first semiconductor layers 111 will be removed and the second semiconductor layers 112 will be patterned to form channel regions. The multi-layer structure is illustrated as including three layers of each of the first semiconductor layers 111 and the second semiconductor layers 112 for illustrative purposes. In some embodiments, the multi-layer structure may include any number of the first semiconductor layers 111 and the second semiconductor layers 112.

In various embodiments, each of the layers of the multi-layer structure may be epitaxially grown using a process such as chemical vapor deposition (CVD), atomic layer deposition (ALD), vapor phase epitaxy (VPE), molecular beam epitaxy (MBE), or the like. Moreover, the first semiconductor layers 111 may be formed of a first semiconductor material, such as silicon germanium, or the like, and the second semiconductor layers 112 may be formed of a second semiconductor material, such as silicon, silicon carbon, or the like. The first semiconductor materials and the second semiconductor materials may be materials having a high-etch selectivity to one another. As such, the first semiconductor layers 111 of the first semiconductor material may be removed without significantly removing the second semiconductor layers 112 of the second semiconductor material, thereby allowing the second semiconductor layers 112 to be patterned to form channel regions.

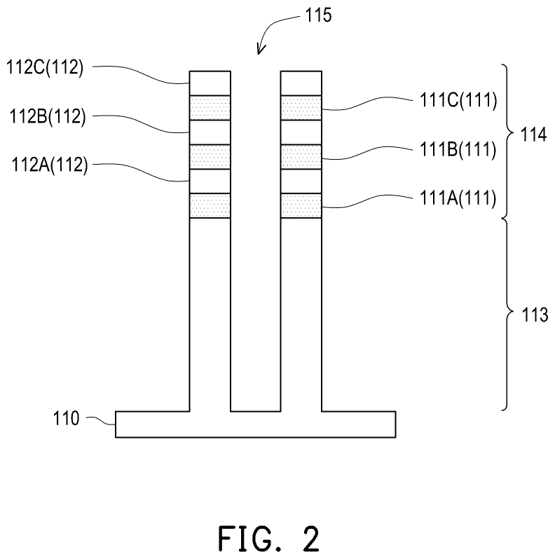

Referring to FIG. 2, fins 113 and stacks 114 are formed in the substrate 110 and the multi-layer structure, in accordance with some embodiments. In some embodiments, the fins 113 and the stacks 114 may be formed by etching trenches 115 in the substrate 110 and the multi-layer structure. For example, the etching includes any acceptable etch process, such as a reactive ion etch (RIE), neutral beam etching (NBE), the like, or a combination thereof. The etching may be anisotropic. During the etching process, a hard mask (not shown) may be used to define a pattern of the fins 113 and the stacks 114. The hard mask includes any suitable insulating material, such as an oxide, a nitride, and oxynitride, and oxycarbonitride, or the like. In some embodiments, the hard mask may be a multi-layer structure. The hard mask may be formed over the stacks 114 using an acceptable process(es) such as thermal oxidation, physical vapor deposition (PVD), CVD, ALD, combinations thereof, or the like.

In various embodiments, the fins 113 and the stacks 114 may be patterned by any suitable method. For example, the fins 113 and the stacks 114 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 113 and the stacks 114.

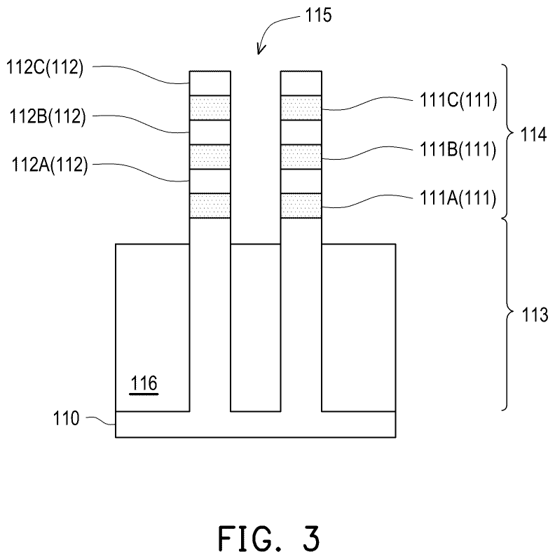

Referring to FIG. 3, shallow trench isolation (STI) regions 116 are formed adjacent the fins 113. The STI regions 116 may be formed by depositing an insulation material to fill the trenches 115 adjacent the fins 113. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. Although the insulation material is illustrated as a single layer, some embodiments may utilize multiple layers, for example, in some embodiments a liner (not separately illustrated) may first be formed along a surface of the substrate 110, the fins 113, and the stacks 114. Thereafter, a fill material, such as those discussed above may be formed over the liner. A removal process is then applied to the insulation material to remove excess insulation material. In some embodiments, a planarization process such as a chemical mechanical polish (CMP), an etch-back process, combinations thereof, or the like may be utilized. After that, the insulation material is then recessed to form the STI regions 116.

In some embodiments, the insulation material is recessed such that upper portions of fins 113 protrude from between neighboring STI regions 116. Further, the top surfaces of the STI regions 116 may be have flat surfaces as illustrated, convex surfaces, concave surfaces (such as dishing), or a combination thereof. The top surfaces of the STI regions 116 may be formed flat, convex, and/or concave by an appropriate etch. The STI regions 116 may be recessed using an acceptable etching process, such as one that is selective to the material of the insulation material (e.g., etches the material of the insulation material at a faster rate than the material of the fins 113 and the stacks 114). For example, an oxide removal using, for example, dilute hydrofluoric (dHF) acid may be used.

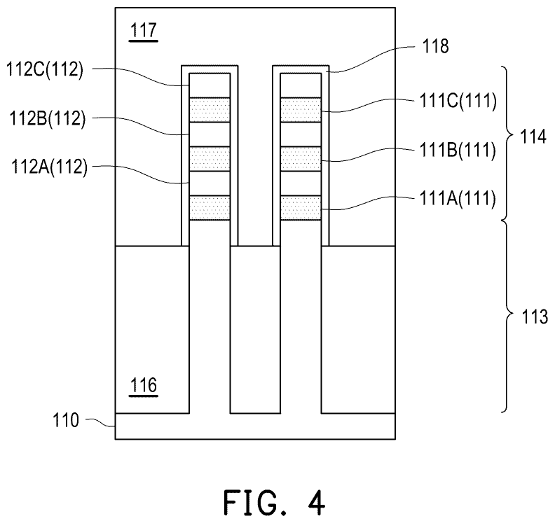

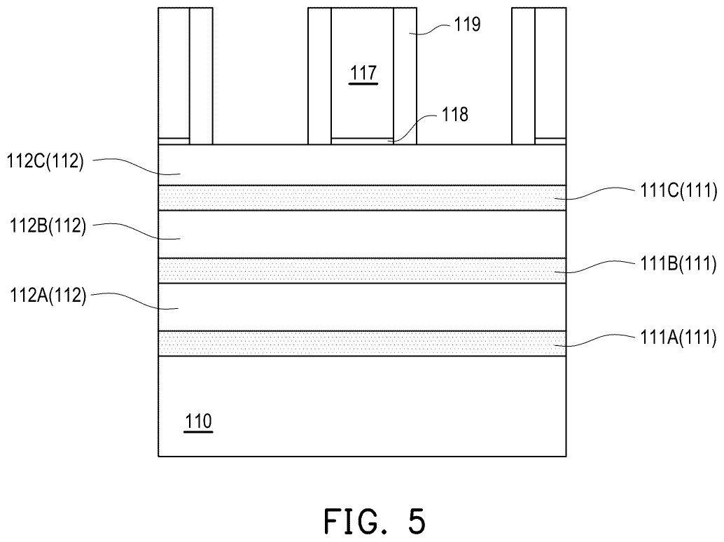

Referring to FIG. 4 and FIG. 5, dummy gates 117 are formed over and along sidewalls of the fins 113 and the stacks 114. To form the dummy gates 117, first, a dummy dielectric material is formed on the fins 113 and/or the stacks 114. The dummy dielectric material may be, for example, silicon oxide, silicon nitride, a combination thereof, or the like, and may be deposited or thermally grown according to acceptable techniques. A dummy gate material is formed over the dummy dielectric material, and a mask layer is formed over the dummy gate material. The dummy gate material may be deposited over the dummy dielectric material and then planarized, such as by a CMP. The mask layer may be deposited over the dummy gate material. Herein, Cross-section of FIG. 4 is perpendicular to cross-section of FIG. 5 in the semiconductor device.

In some embodiments, the dummy gate material may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate material may be deposited by physical vapor deposition (PVD), CVD, sputter deposition, or other techniques for depositing the selected material. The dummy gate material may be made of other materials that have a high etching selectivity from the etching of isolation regions. Further, the mask layer may include, for example, silicon nitride, silicon oxynitride, or the like. Subsequently, the mask layer may be patterned using acceptable photolithography and etching techniques to form masks (not shown). The pattern of the mask layer then may be transferred to the dummy gate material and to the dummy dielectric material to form dummy gates 117 and dummy gate dielectrics 118, respectively. The dummy gates 117 cover respective channel regions of the second semiconductor layers 112.

In the unillustrated embodiment, the dummy gates 117 may also have a lengthwise direction substantially perpendicular to the lengthwise direction of respective fins 113. Moreover, the dummy gate dielectrics 118 may be deposited such that the dummy gate dielectrics 118 covers the STI regions 116, such that the dummy gate dielectrics 118 extends between the dummy gates 117 and the STI regions 116.

In FIG. 5, gate spacers 119 may be formed over the stacks 114, the dummy gates 117, and the dummy gate dielectrics 118. For example, the gate spacers 119 are formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 117 (thus forming the gate spacers 119).

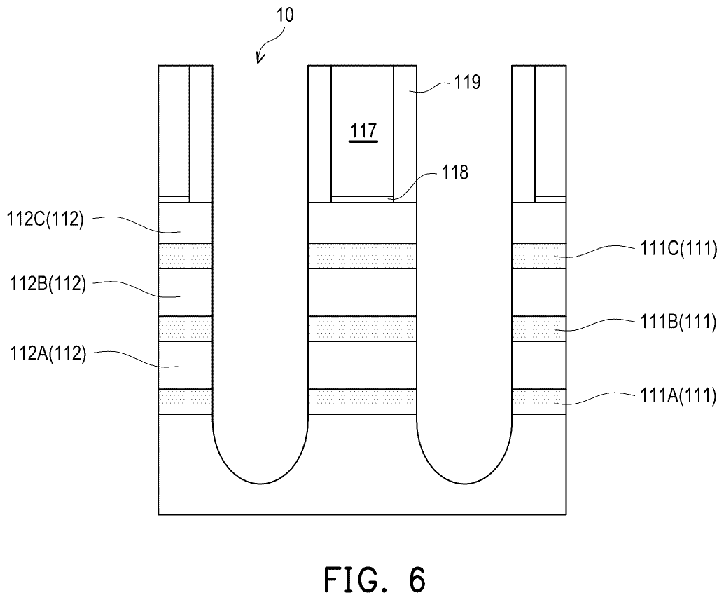

Referring to FIG. 6, source/drain recesses 10 are formed in the stacks 114, and the substrate 110, in accordance with some embodiments. Epitaxial source/drain regions will be subsequently formed in the source/drain recesses 10. The source/drain recesses 10 may extend through the first semiconductor layers 111 and the second semiconductor layers 112, and into the substrate 110. The source/drain recesses 10 may be formed by etching the fins 113, the stacks 114, and the substrate 110 using anisotropic etching processes, such as RIE, NBE, or the like. The gate spacers 119, portions of the stacks 114, and the substrate 110 during the etching processes used to form the source/drain recesses 10. Timed etch processes may be used to stop the etching of the source/drain recesses 10 after the source/drain recesses 10 reach a desired depth.

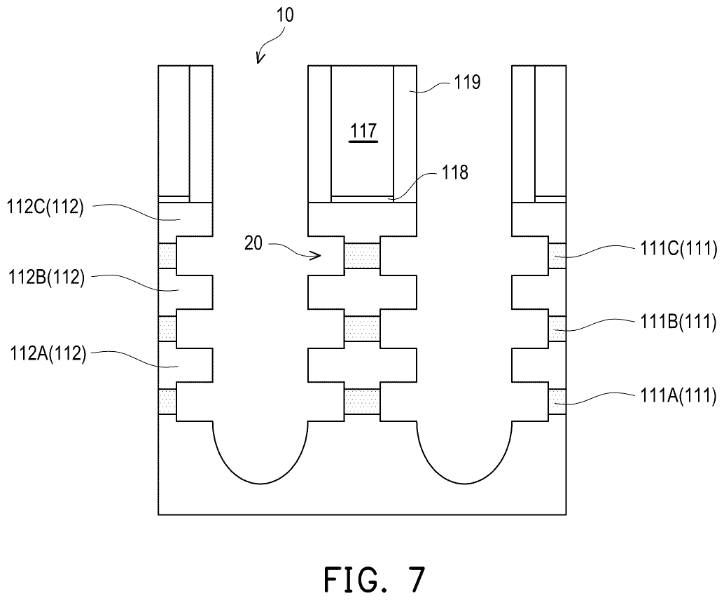

Referring to FIG. 7, the etch process may be selective to the material of the first semiconductor layers 111 and remove the first semiconductor layers 111 without significantly removing the second semiconductor layers 112 or the substrate 110. In an embodiment in which the first semiconductor layers 111 include, e.g., SiGe, and the second semiconductor layers 112 include, e.g., Si or SiC, a dry etch process with tetramethylammonium hydroxide (TMAH), ammonium hydroxide (NH₄OH), or the like may be used to remove portions of the first semiconductor layers 111 to form inner spacer recesses 20.

In the illustrated embodiment, the second semiconductor layers 112 are partially recessed, and the inner spacer recesses 20 may extend toward overlying second semiconductor layer 112 and underlying second semiconductor layer 112, such that entire sidewalls of the first semiconductor layers 111 and portions of sidewalls of the second semiconductor layers 112 may be exposed by the inner spacer recesses 20.

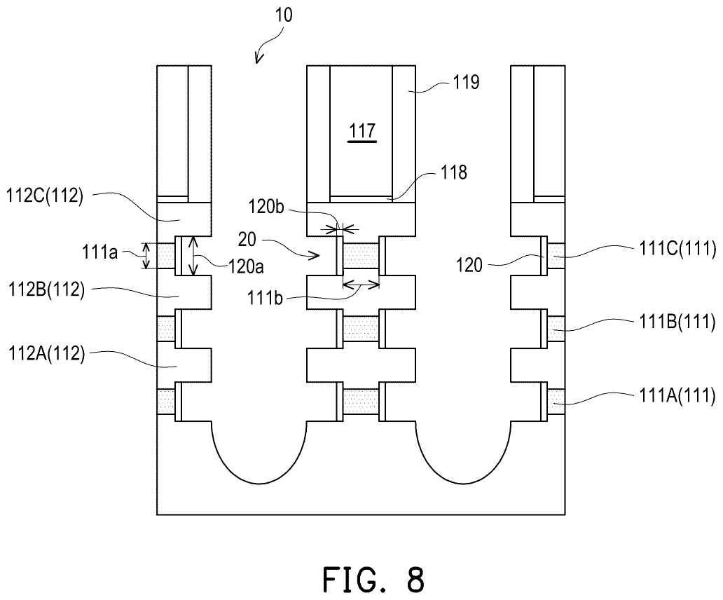

Referring to FIG. 8, forming first dielectric layers 120 in the inner spacer recesses 20. In some embodiments, an operation may include blanket deposition of a dielectric material layer (not shown) over the substrate 110, and etch-back of the dielectric material layer. In some implementations, the dielectric material layer may be deposited using CVD, PECVD, LPCVD, ALD or other suitable method. The first dielectric layers 120 may include oxide, a nitride, or the like. In some embodiments, oxide may include metal oxides or silicon oxide. The metal oxides here may include aluminum oxide, zirconium oxide, tantalum oxide, yttrium oxide, titanium oxide, lanthanum oxide, or other suitable metal oxide.

In some implementations, the first dielectric layers 120 are occupied part spaces of the inner spacer recesses 20 but not extend into the source/drain recesses 10, thereby, the first dielectric layers 120 may be spaced apart from the source/drain recesses 10 by the inner spacer recesses 20, for example, the first dielectric layers 120 may be fully formed in the inner spacer recesses 20 (not shown), and then an etching back process is performed, such that the location of the first dielectric layers 120 may be controlled. Moreover, the sidewalls of the first semiconductor layers 111 and the second semiconductor layers 112 exposed in the inner spacer recesses 20 may be covered by the first dielectric layers 120, such that a size (such as a height 120a) of each of the first dielectric layers 120 is greater than a size (such as a height 111a) of each of the first semiconductor layers 111 adjacent thereof.

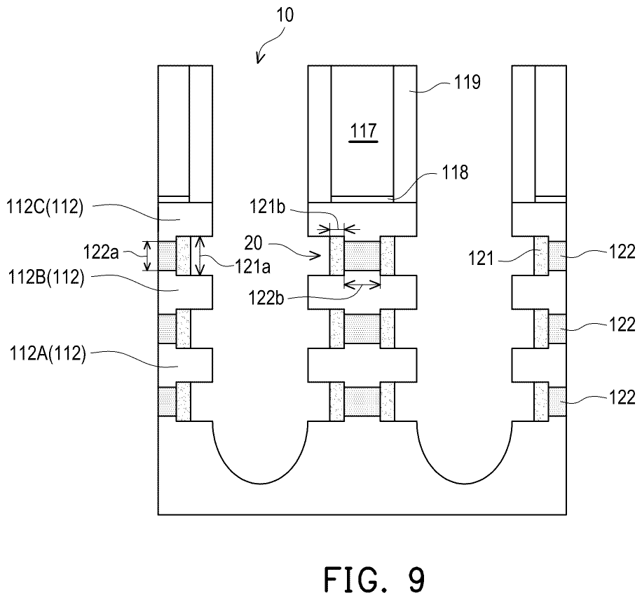

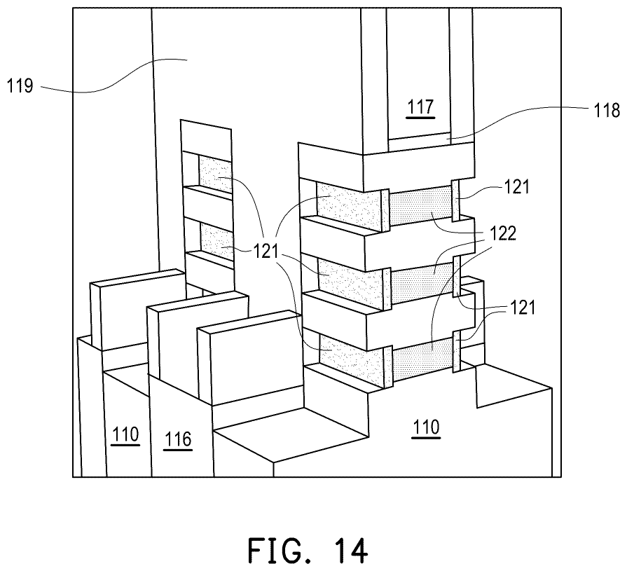

Referring to FIG. 9 and FIG. 14, performing a thermal treatment to convert the first dielectric layers 120 into second dielectric layers 121 as well as convert a remaining portion of the first semiconductor layers 111 into condensation layers 122. During the thermal treatment, transformation of the second dielectric layers 121 and condensation layers 122 may cause tensile strain to the second semiconductor layers 112, by doing so, the tensile strain introduced in the structure may enhance mobility in the semiconductor device, thereby the performance of the semiconductor device is improved. In some embodiments, the device may be NMOS FET or the like.

As an example, after thermal treatment, part of atoms in the remaining portion of the first semiconductor layers 111 may be oxidized, and another part of atoms in the remaining portion of the first semiconductor layers 111 may be reduced (atoms away from the inner spacer recesses 20), in this way, a size of the first dielectric layers 120 may be increased vertically and horizontally to form second semiconductor layers 121, while the remaining portion of the first semiconductor layers 111 may be compressed inward to form the condensation layers 122, and concentration of reduced atoms in remaining portion of the first semiconductor layers 111 may be increased. Depending on aforementioned manner, the tensile strain may occur between these components.

In FIG. 8 and FIG. 9, size changes may be as follow. A height 121a and a width 121b of the second dielectric layer 121 is greater than a height 120a and a width 120b of the first dielectric layer 120. Moreover, a height 122a of the condensation layer 122 is greater than a height 111a of the remaining portion of the remaining portion of first semiconductor layer 111, and a width 122b of the condensation layer 122 is smaller than a width 111b of the remaining portion of the first semiconductor layer 111.

Further in FIG. 8 and FIG. 9, concentration changes may be as follow. Reduced atoms may be germanium, such that germanium concentration of the remaining portion of the first semiconductor layer 111 is lower than germanium concentration of the condensation layer 122. For example, germanium concentration of the remaining portion of the first semiconductor layer 111 is lower than 40%, and germanium concentration of the condensation layer 122 in a range from about 40% to about 60%.

In certain embodiments, the thermal treatment is performed at a temperature in a range from about 400° C. to about 600° C. In an embodiment, a wet oxidation process with hydrogen and oxygen is used. In another embodiment, after wet oxidation process or at the same period as wet oxidation process conducted, an annealing process with hydrogen is further performed, by doing so, atomic reduction effect in the condensation layers 122 may be further improved, thereby tensile strain may be more significant. It should be noted that, the wet oxidation process is different from the annealing process, and the annealing process is optional.

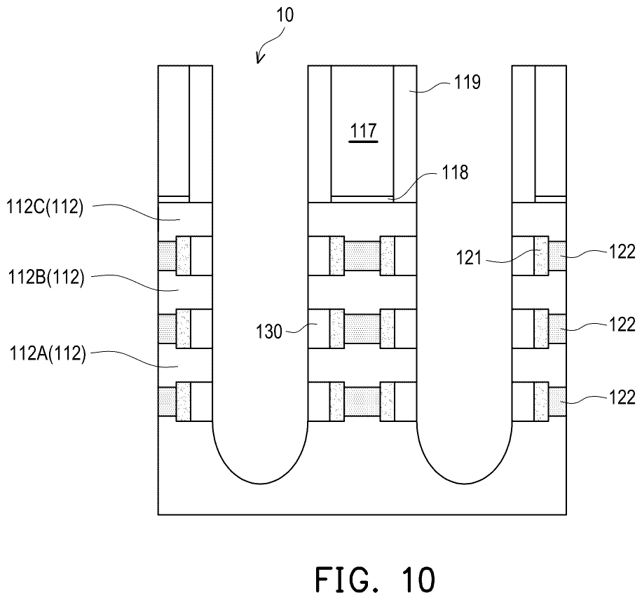

Referring to FIG. 10, inner spacer features 130 are formed in the inner spacer recesses 20 and on the sidewalls of the second dielectric layers 121. The inner spacer features 130 may be act as isolation features between subsequently formed source/drain regions and a gate structure. As will be discussed in greater detail below, source/drain regions will be formed in the source/drain recesses 10, while the condensation layers 122 will be replaced with corresponding gate structures. The inner spacer features 130 may also be used to prevent damage to subsequently formed source/drain regions by subsequent etching processes, such as etching processes used to form gate structures.

The inner spacer features 130 may be formed by depositing an inner spacer layer (not separately illustrated) over the structures illustrated in FIG. 9. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacer features 130. The inner spacer layer may be etched by an anisotropic etching process, such as RIE, NBE, or the like. Materials of the inner spacer inner spacer features 130 may be different from materials of the second dielectric layers 121.

Although FIG. 10 illustrates outer sidewalls of the inner spacer features 130 as being flush with sidewalls of the second semiconductor layers 112, however, in other embodiment, the outer sidewalls of the inner spacer features 130 may extend beyond or be recessed from sidewalls of the second semiconductor layers 112. Moreover, although the outer sidewalls of the inner spacer features 130 are illustrated as being straight in FIG. 10, the outer sidewalls of the inner spacer features 130 may be concave or convex.

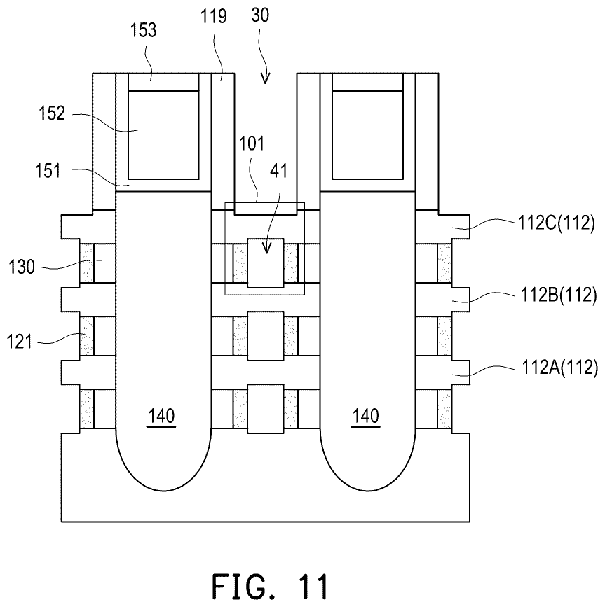

Referring to FIG. 11, source/drain features 140 may be formed in the source/drain recesses 10 by epitaxial processes. Suitable epitaxial processes include CVD deposition techniques (e.g., vapor-phase epitaxy (VPE) and/or ultra-high vacuum CVD (UHV-CVD)), molecular beam epitaxy (MBE), and/or other suitable processes. In some embodiments, the source/drain features 140 include silicon doped with a second n-type dopant different from the first n-type dopant. In some embodiments, the second n-type dopant is phosphorus (P) and the source/drain features 140 include silicon and phosphorus. In some embodiments, the source/drain features 140 may be in contact with the inner spacer features 130 and the second semiconductor layers 112.

And then, etching stop material layers 151 may be formed over the substrate 110, deposition of interlayer dielectric material layers 152 and cap layers 153 over the etching stop material layers 151. In some examples, the etching stop material layers 151 and cap layers 153 may include a silicon nitride layer, a silicon oxide layer, a silicon oxynitride layer, and/or other materials. the etching stop material layers 151 and cap layers 153 may be formed by ALD, plasma-enhanced chemical vapor deposition (PECVD) process and/or other suitable deposition or oxidation processes. In some embodiments, the interlayer dielectric material layers 152 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The interlayer dielectric material layers 152 may be deposited by a PECVD process or other suitable deposition technique. As shown in FIG. 11, the etching stop material layers 151 may be formed directly on top surfaces of the source/drain features 140.

Furthermore, the removal process of the dummy gates 117 and the dummy gate dielectrics 118 may be performed. The removal process includes one or more etching processes that are selective to the material in the dummy gates 117 and the dummy gate dielectrics 118. In some embodiments, the removal of the dummy gates 117 and the dummy gate dielectrics 118 are performed using as a selective wet etch, a selective dry etch, or a combination thereof that is selective to the dummy gates 117 and the dummy gate dielectrics 118. After the removal of the dummy gates 117 and the dummy gate dielectrics 118, upper gate trenches 30 are formed.

In some implementations, the upper gate trenches 30 may penetrate through portions of the uppermost channel layer 112 (such as the second semiconductor layer 112C), in this way, bottom surfaces of the upper gate trenches 30 are lower than bottom surfaces of the gate spacers 119.

After the removal of the dummy gates 117 and the dummy gate dielectrics 118, the condensation layers 122 are removed to form first interposing openings 41. In some embodiments, the removal method may include operations to selectively remove the condensation layers 122 between the second semiconductor layers 112. The selective removal of the condensation layers 122 release the second semiconductor layers 112 and the second semiconductor layers 112 may be referred to channel layers 112, wherein parallel channel layers 112 spaced apart from one another, source/drain features 140 are disposed besides the channel layers 112, and the inner spacer features 130 are disposed between the channel layers 112. The selective removal of the condensation layers 122 may be implemented by selective dry etch, selective wet etch, or other selective etch processes.

In some embodiments, for ensuring removal of the condensation layers 122, portions of the channel layers 112 may be removed, such that the first interposing openings 41 are recessed in the channel layers 112. Alternatively, the first interposing openings 41 are not recessed in the channel layers 112.

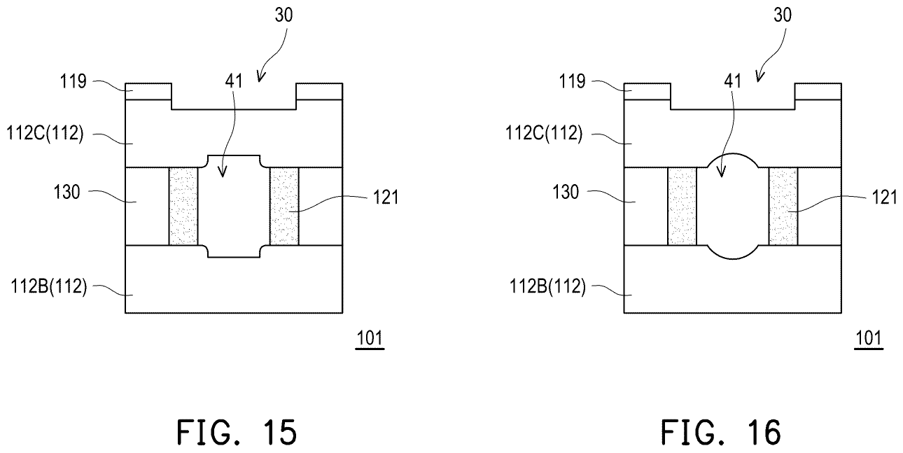

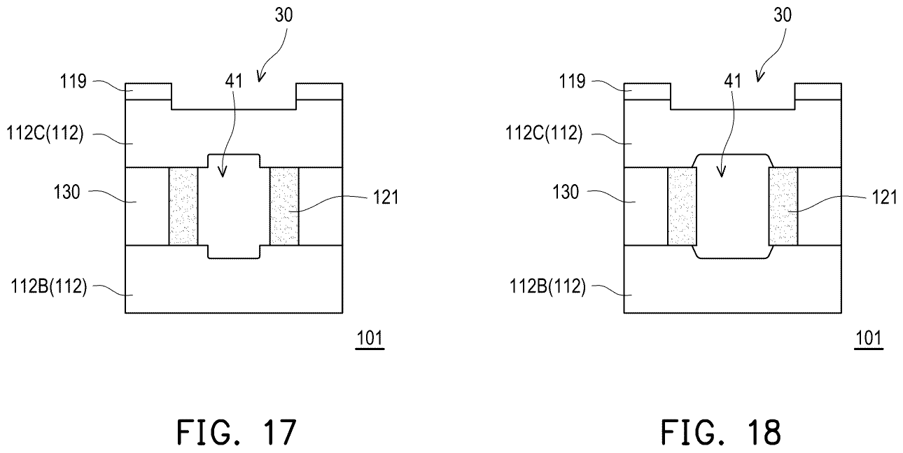

Although FIG. 11 illustrates right angle (about 90 degree) in top corners of the first interposing openings 41, however, other implementations are possible, such as solid frame 101 in other figures. In FIG. 15, intersections between the first interposing openings 41 and the second dielectric layers 121 may be rounding. In FIG. 16, top surfaces of the first interposing openings 41 may be arch-shaped, not plateau-shaped. In FIG. 17, top corners of the first interposing openings 41 may be rounding angle (not 90 degree). In FIG. 18, the first interposing openings 41 may extend above on the second dielectric layers 121.

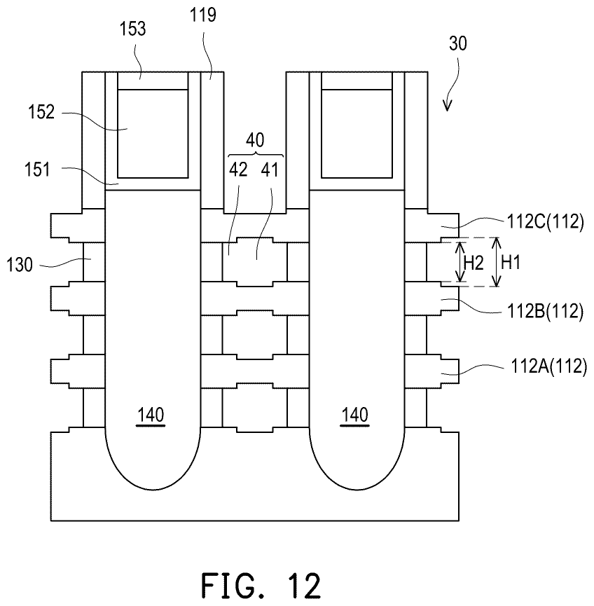

Referring to FIG. 12, the second dielectric layers 121 are removed to form second interposing openings 42, wherein a pair of second interposing openings 42 located at opposite sides of the first interposing opening 41, the first interposing openings 41 and second the interposing openings 42 may be collectively referred to as gate opening 40. In some embodiments, the removal method may include operations to selectively remove the second dielectric layers 121 between the second channel layers 112. The selective removal of the second dielectric layers 121 may be implemented by selective dry etch, selective wet etch, or other selective etch processes, and etchant in the removal of the second dielectric layer 121 may be different from etchant in the removal of the condensation layers 122.

In the illustrated embodiment, size (e.g., height H1) of the first interposing openings 41 may be greater than size (e.g., height H2) of the second the interposing openings 42. In alternatively embodiment (not shown), size (e.g., height H1) of the first interposing openings 41 may be equal to size (e.g., height H2) of the second the interposing openings 42.

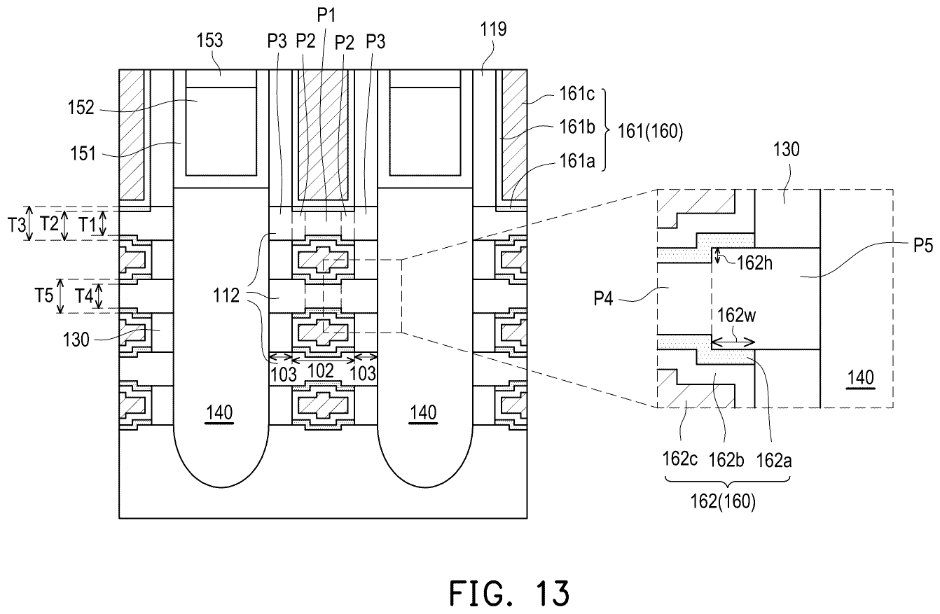

Referring to FIG. 13, gate structures 160 are formed to wrap around the channel layers 112 and the source/drain structures 140 disposed at opposite sides of the gate structures 160. The gate structures 160 may be a high-K metal gate structure. In some embodiments, the gate structures 160 are formed within the upper gate trenches 30 and into the gate openings 40 including the first interposing openings 41 and the second the interposing openings 42 (the space left behind by the removal of the condensation layers 122 and the second dielectric layers 121). In this regard, each of the gate structures 160 includes an upper gate feature 161 and interposing gate features 162 between the channel layers 112, and the gate spacers 119 along sidewalls of the upper gate feature 161.

For example, between the two adjacent source/drain features 140, the number of the upper gate feature 161 is one and the number of the interposing gate features 162 are three, as shown in FIG. 13. It should be noted that a number of the aforementioned interposing gate features 162 which are for illustrative purposes only and not intended to be limiting beyond what is specifically recited in the claims. It can be appreciated that any number of interposing gate features 162 can be formed.

In the illustrated embodiment, the upper gate feature 161 includes a dielectric layer 161a, a dielectric layer 161b formed over the dielectric layer 161a, and a gate electrode layer 161c formed over the dielectric layer 161b. The dielectric layer 161a may be an interfacial layer and the dielectric layer 161b may be high-K gate dielectric layer. Moreover, each of the interposing gate features 162 includes a dielectric layer 162a, a dielectric layer 162b formed over the dielectric layer 162a, and a gate electrode layer 162c formed over the dielectric layer 162b. The dielectric layer 162a may be an interfacial layer and the dielectric layer 162b may be high-K gate dielectric layer.

In some embodiments, high-K gate dielectrics, as used and described herein, include dielectric materials having a high dielectric constant, for example, greater than that of thermal silicon oxide. The gate electrode layer 161c, 162c used within the gate structure 160 may include a metal, metal alloy, or metal silicide, for example, the gate electrode layer 161c, 162c include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In some embodiments, the dielectric layer 161a, 161b, 162a, 162b are formed by ALD, physical vapor deposition (PVD), CVD, oxidation, and/or other suitable methods, and the gate electrode layer 161c, 162c are formed by ALD, PVD, CVD, e-beam evaporation, or other suitable process.

In FIG. 13, each of the interposing gate features 162 includes protrusions protruding into the channel layers 112, and a height of the inner spacer feature 130 is smaller than a maximum height of the interposing gate feature 162 due to the different sizes of the first interposing opening 41 and the second interposing opening 42.

For example, each of the interposing gate features 162 includes a central region and a pair of edge region located at opposite sides of the central region, the protrusions are located in the central region. Further, an uppermost interposing gate feature 162 underlies the upper gate feature 161, and an uppermost inner spacer feature 130 underlies the gate spacers 119. In some embodiments, a distance between the upper gate feature 161 and the central region of the uppermost interposing gate feature 162 is smaller than a distance between the upper gate feature 161 and the edge regions of the uppermost interposing gate feature 162. In some embodiments, a distance between the upper gate feature 161 and the central region of the uppermost interposing gate feature 162 is smaller than a distance between the gate spacer 119 and the uppermost inner spacer 130.

In some embodiments, the protrusions are laterally spaced apart from the source/drain structures 140. Each of the protrusions has a height 162h in a range from about 0.1 nm to about 3 nm. Further, a width 162w between each of the protrusions and the inner spacer features 130 in a range from about 0.1 nm to about 5 nm.

In some embodiments, the central region of each of the interposing gate features 162 comprises an upper protrusion and a lower protrusion, the upper protrusion protrudes into a first channel layer (such as the channel layer 112C), and the lower protrusion protrudes into a second channel layer (such as the channel layer 112B).

In one section of the semiconductor device, an uppermost channel layer 112 disposed between the upper feature 161 and an uppermost interposing feature 162 includes a first portion P1, a pair of second portions P2 at opposite sides of the first portion P1, and a pair of third portions P3 at opposite sides of the second portions P2, in this regard, the third portions P3 and the second portions P2 may be laterally located between the first portion P1 and the source/drain features 140, and the first portion P1 and the second portions P2 in the central portion 102 of each of the channel layers 112 may be spaced apart from the inner spacer features 130.

In some embodiments, the central portion 102 of the channel layers 112 is aligned the gate structure 160 in a vertical direction, and the edge portions 103 of the channel layers 112 are aligned the inner spacer features 130 in the vertical direction. The edge portions 103 of an uppermost channel layer 112 are disposed between the gate spacers 119 and the inner spacer features 130. The edge portions 103 of an uppermost channel layer 112 are directly in contact with the gate spacers 119 and the source/drain structures 140.

By protrusions, a thickness T1 of the first portion P1 or a thickness T2 of the second portion P2 in the central portion 102 of the channel layer 112 is smaller than a thickness T3 of the third portion P3 in the edge portion 103 of the channel layer 112. Moreover, a thickness T1 of first portion P1 is smaller than a thickness T2 of the second portion P2, thereby a bottom surface of the first portion P1 is higher than a bottom surface of the second portion P2.

In another section of the semiconductor device, an underlying channel layer 112 disposed between the interposing features 162 includes a fourth portion P4 and fifth portions P5 at opposite sides of the fourth portion P4. By protrusions, a thickness T4 of the fourth portion P4 in the central portion 102 of each of the channel layers 112 is smaller than a thickness T5 of the fifth portions P5 in the edge portion 103 of each of the channel layers 112.

In accordance with some embodiments of the present disclosure, a semiconductor device includes a substrate; channel layers disposed over the substrate, wherein the channel layers are spaced apart from one another; a gate structure disposed on the substrate and wrapping around the channel layers, wherein the gate structure comprises an upper gate feature and interposing gate features between the channel layers, wherein the interposing gate features comprise protrusions protruding into the channel layers; and source/drain structures disposed besides the channel layers and at opposite sides of the gate structure. In an embodiment, the protrusions are laterally spaced apart from the source/drain structures. In an embodiment, each of the interposing gate features comprises a central region and a pair of edge regions located at opposite sides of the central region, and the central region of each of the interposing gate features comprises an upper protrusion and a lower protrusion, the upper protrusion protrudes into a first channel layer among the channel layers, and the lower protrusion protrudes into a second channel layer among the channel layers. In an embodiment, an uppermost interposing gate feature among the interposing gate features underlies the upper gate feature, a distance between the upper gate feature and the central region of the uppermost interposing gate feature is smaller than a distance between the upper gate feature and the edge regions of the uppermost interposing gate feature. In an embodiment, semiconductor device further includes inner spacer features disposed between the channel layers and besides at opposite sides of the interposing gate features, wherein a height of each of the inner spacer features is smaller than a maximum height of each of the interposing gate features. In an embodiment, semiconductor device further includes gate spacers along sidewalls of the upper gate feature, wherein an uppermost interposing gate feature among the interposing gate features underlies the upper gate feature, an uppermost inner spacer feature among the inner spacer features underlies the gate spacers, a distance between the upper gate feature and the central region of the uppermost interposing gate feature is smaller than a distance between the gate spacer and the uppermost inner spacer.

In accordance with some embodiments of the present disclosure, a semiconductor device includes parallel channel layers spaced apart from one another; a gate structure wrapping around the channel layers, wherein the gate structure comprises an upper gate feature and interposing gate features between the channel layers, wherein each of the channel layers comprises a central portion and a pair of edge regions at opposite sides of the central portion, and a thickness of the central portion is smaller than a thickness of each of the edge regions; and source/drain structures disposed besides the channel layers and at opposite sides of the gate structure. In an embodiment, an uppermost interposing gate feature among the interposing gate features underlies the upper gate feature, an uppermost channel layer among the channel layers is disposed between the upper feature and the uppermost interposing feature, and the central portion of the uppermost channel layer comprises a first portion and a pair of second portions at opposite sides of the first portion, a thickness of the first portion is smaller than a thickness of each of the second portions, and the thickness of each of the second portions is smaller than the thickness of each of the edge portions. In an embodiment, the edge portions and the second portions are laterally located between the first portion and the source/drain structures. In an embodiment, a bottom surface of the first portion is higher than a bottom surface of each of the second portions. In an embodiment, semiconductor device further includes inner spacer features disposed between the channel layers and besides at opposite sides of the interposing gate features, wherein the central portion of the channel layers is spaced apart from the inner spacer features. In an embodiment, the central portion of the channel layers is aligned the gate structure in a vertical direction, and the edge portions of the channel layers are aligned the inner spacer features in the vertical direction. In an embodiment, semiconductor device further includes gate spacers along sidewalls of the upper gate feature, wherein the edge portions of the channel layers are disposed between the gate spacers and the inner spacer features. In an embodiment, the edge portions of the channel layers are directly in contact with the gate spacers and the source/drain structures.

In accordance with some embodiments of the present disclosure, a manufacturing method of a semiconductor device includes forming a stack of alternating semiconductor layers on a substrate, wherein the stack has a first semiconductor layer and a second semiconductor layer; removing portions of the first semiconductor layer to form an inner spacer recess in the stack; forming a first dielectric layer in the inner spacer recess; performing a thermal treatment to convert the first dielectric layer into a second dielectric layer as well as convert a remaining portion of the first semiconductor layer into a condensation layer, wherein germanium concentration of the remaining portion of the first semiconductor layer is lower than germanium concentration of the condensation layer; forming an inner spacer feature in the inner spacer recess; removing the second dielectric layer and the condensation layer to form a gate opening; and forming a gate structure in the gate opening. In an embodiment, the thermal treatment comprises an oxidation process or a combination of the oxidation process and annealing process. In an embodiment, a height and a width of the second dielectric layer is greater than a height and a width of the first dielectric layer. In an embodiment, a width of the condensation layer is smaller than a width of the remaining portion of the first semiconductor layer, and a height of the condensation layer is greater than a height of the remaining portion of the first semiconductor layer. In an embodiment, the step of removing the second dielectric layer and the condensation layer further comprising: removing the condensation layer to form a first interposing opening; and removing the second dielectric layer to form a second interposing opening, wherein a size of the first interposing opening is different from a size of the second interposing opening. In an embodiment, the step of removing the condensation layer further comprising: removing portions of the channel layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
channel layers disposed over the substrate, wherein the channel layers are spaced apart from one another;
a gate structure disposed on the substrate and wrapping around the channel layers, wherein the gate structure comprises an upper gate feature and interposing gate features between the channel layers, wherein the interposing gate features comprise protrusions protruding into the channel layers; and
source/drain structures disposed besides the channel layers and at opposite sides of the gate structure.

2. The semiconductor device as claimed in claim 1, wherein the protrusions are laterally spaced apart from the source/drain structures.

3. The semiconductor device as claimed in claim 1, wherein each of the interposing gate features comprises a central region and a pair of edge regions located at opposite sides of the central region, and the central region of each of the interposing gate features comprises an upper protrusion and a lower protrusion, the upper protrusion protrudes into a first channel layer among the channel layers, and the lower protrusion protrudes into a second channel layer among the channel layers.

4. The semiconductor device as claimed in claim 3, wherein an uppermost interposing gate feature among the interposing gate features underlies the upper gate feature, a distance between the upper gate feature and the central region of the uppermost interposing gate feature is smaller than a distance between the upper gate feature and the edge regions of the uppermost interposing gate feature.

5. The semiconductor device as claimed in claim 1, further comprising inner spacer features disposed between the channel layers and besides at opposite sides of the interposing gate features, wherein a height of each of the inner spacer features is smaller than a maximum height of each of the interposing gate features.

6. The semiconductor device as claimed in claim 5, further comprising gate spacers along sidewalls of the upper gate feature, wherein an uppermost interposing gate feature among the interposing gate features underlies the upper gate feature, an uppermost inner spacer feature among the inner spacer features underlies the gate spacers, a distance between the upper gate feature and the central region of the uppermost interposing gate feature is smaller than a distance between the gate spacer and the uppermost inner spacer.

7. A semiconductor device, comprising:
parallel channel layers spaced apart from one another;
a gate structure wrapping around the channel layers, wherein the gate structure comprises an upper gate feature and interposing gate features between the channel layers, wherein each of the channel layers comprises a central portion and a pair of edge regions at opposite sides of the central portion, and a thickness of the central portion is smaller than a thickness of each of the edge regions; and
source/drain structures disposed besides the channel layers and at opposite sides of the gate structure.

8. The semiconductor device as claimed in claim 7, wherein an uppermost interposing gate feature among the interposing gate features underlies the upper gate feature, an uppermost channel layer among the channel layers is disposed between the upper feature and the uppermost interposing feature, and the central portion of the uppermost channel layer comprises a first portion and a pair of second portions at opposite sides of the first portion, a thickness of the first portion is smaller than a thickness of each of the second portions, and the thickness of each of the second portions is smaller than the thickness of each of the edge portions.

9. The semiconductor device as claimed in claim 8, wherein the edge portions and the second portions are laterally located between the first portion and the source/drain structures.

10. The semiconductor device as claimed in claim 8, wherein a bottom surface of the first portion is higher than a bottom surface of each of the second portions.

11. The semiconductor device as claimed in claim 7, further comprising inner spacer features disposed between the channel layers and besides at opposite sides of the interposing gate features, wherein the central portion of the channel layers is spaced apart from the inner spacer features.

12. The semiconductor device as claimed in claim 11, wherein the central portion of the channel layers is aligned the gate structure in a vertical direction, and the edge portions of the channel layers are aligned the inner spacer features in the vertical direction.

13. The semiconductor device as claimed in claim 12, further comprising gate spacers along sidewalls of the upper gate feature, wherein the edge portions of the channel layers are disposed between the gate spacers and the inner spacer features.

14. The semiconductor device as claimed in claim 13, wherein the edge portions of the channel layers are directly in contact with the gate spacers and the source/drain structures.

15. A manufacturing method of a semiconductor device, comprising:
forming a stack of alternating semiconductor layers on a substrate, wherein the stack has a first semiconductor layer and a second semiconductor layer;
removing portions of the first semiconductor layer to form an inner spacer recess in the stack;
forming a first dielectric layer in the inner spacer recess;
performing a thermal treatment to convert the first dielectric layer into a second dielectric layer as well as convert a remaining portion of the first semiconductor layer into a condensation layer, wherein germanium concentration of the remaining portion of the first semiconductor layer is lower than germanium concentration of the condensation layer;
forming an inner spacer feature in the inner spacer recess;
removing the second dielectric layer and the condensation layer to form a gate opening; and
forming a gate structure in the gate opening.

16. The manufacturing method of a semiconductor device as claimed in claim 15, wherein the thermal treatment comprises an oxidation process or a combination of the oxidation process and annealing process.

17. The manufacturing method of a semiconductor device as claimed in claim 15, wherein a height and a width of the second dielectric layer is greater than a height and a width of the first dielectric layer.

18. The manufacturing method of a semiconductor device as claimed in claim 15, wherein a width of the condensation layer is smaller than a width of the remaining portion of the first semiconductor layer, and a height of the condensation layer is greater than a height of the remaining portion of the first semiconductor layer.

19. The manufacturing method of a semiconductor device as claimed in claim 15, wherein the step of removing the second dielectric layer and the condensation layer further comprising:
removing the condensation layer to form a first interposing opening; and
removing the second dielectric layer to form a second interposing opening, wherein a size of the first interposing opening is different from a size of the second interposing opening.

20. The manufacturing method of a semiconductor device as claimed in claim 19, wherein the step of removing the condensation layer further comprising: removing portions of the channel layers.
